(19) United States
(12) Patent Application Publication
(10) Pub. No.: US 2025/0127010 A1
(43) Pub. Date: Apr. 17, 2025

(54) Display Panel and Display Device

(71) Applicant: HKC CORPORATION LIMITED, Shenzhen (CN)

(72) Inventors: Guangping WEI, Shenzhen (CN); Junfeng XIE, Shenzhen (CN)

(73) Assignee: HKC CORPORATION LIMITED, Shenzhen (CN)

(21) Appl. No.: 18/913,992

(22) Filed: Oct. 11, 2024

(30) Foreign Application Priority Data
Oct. 12, 2023 (CN) 202311316570.7

(51) Int. Cl. H10K 59/50; G02F 1/137; G02F 1/155; H10K 59/128; H10K 59/80

(52) U.S. Cl. CPC H10K 59/50; G02F 1/137; G02F 1/155; H10K 59/128; H10K 59/8051; H10K 59/878; H10K 59/8792

(57) ABSTRACT

The present disclosure relates to a display panel and a display device. The display panel includes a substrate and a plurality of light-emitting units provided above the substrate, wherein an electrochemical micro-reaction structure is formed on a side of the substrate away from at least one of the light-emitting units, and the light-emitting unit emits light toward the electrochemical micro-reaction structure; the electrochemical micro-reaction structure has a mirror state in which the light emitted toward the electrochemical micro-reaction structure is reflected, and light with a large angle is emitted from a gap between front side display pixels of the display panel, thus disturbing light with a large viewing angle of the front side display pixels, so as to realize the peep preventing function during front side displaying and increase a pixel aperture ratio of the display panel.

### CROSS-REFERENCE TO RELATED APPLICATIONS

The present disclosure claims all the benefits of Chinese patent application No. 202311316570.7 filed on Oct. 12, 2023 before the China National Intellectual Property Administration of the People's Republic of China, entitled “Display Panel and Display Device”, which is explicitly incorporated herein by reference in its entirety.

### FIELD

The disclosure relates to the technical field of display, in particular to a display panel and a display device.

### BACKGROUND

An OLED (Organic Light-Emitting Diode) display panel has advantages of self-luminescence, flexibility, thin thickness, high brightness, low power consumption, fast response and a wide color gamut, and is widely used in electronic products such as televisions, mobile phones and notebooks. With a wider viewing angle, the display panel can bring better visual experience to users, but sometimes the users also hope that the display panel can prevent a peep, thus effectively protecting commercial secrets and personal privacy.

Most of the present OLED display panels adopt a structure design of peep preventing sub-pixels to achieve a peep preventing function, which results in a fact that when the display panel does not need the peep preventing function, the structure that realizes the peep preventing function still occupies an aperture ratio, and the display panel has a small pixel aperture ratio in effective displaying.

### SUMMARY

The disclosure provides a display panel and a display device, so as to solve a problem of a small aperture ratio of a display panel with a peep preventing function.

In a first aspect, the disclosure provides a display panel including a substrate and a plurality of light-emitting units provided above the substrate, wherein an electrochemical micro-reaction structure is formed on a side of the substrate away from at least one of the light-emitting units, and the light-emitting unit emits light toward the electrochemical micro-reaction structure;
the electrochemical micro-reaction structure has a mirror state in which the light emitted toward the electrochemical micro-reaction structure is reflected by the electrochemical micro-reaction structure.

In some embodiments, the electrochemical micro-reaction structure includes a first transparent electrode and a second transparent electrode, between which a cavity is formed, a metal cation electrolyte is provided in the cavity, and a smooth layer is formed on a side of the first transparent electrode toward the second transparent electrode.

In some embodiments, the electrochemical micro-reaction structure is embedded in a side of the substrate away from the light-emitting unit which is further provided with a shielding layer, and an avoidance part is formed at a part of the shielding layer corresponding to the electrochemical micro-reaction structure.

In some embodiments, the second transparent electrode is located on a side of the first transparent electrode away from the light emitting unit, and a rough layer is formed on a side of the second transparent electrode facing the first transparent electrode.

In some embodiments, an orthogonal projection of the first transparent electrode in a thickness direction of the substrate is in a shape of an arc, a broken line or a polygon.

In some embodiments, a driving circuit layer is further provided between the substrate and the light emitting unit and is connected with the first transparent electrode and the second transparent electrode, causing a voltage difference between the first transparent electrode and the second transparent electrode.

In some embodiments, the light-emitting unit is electrically connected with the driving circuit layer and includes a second light-emitting layer and a first light-emitting layer having opposite light-emitting directions.

In some embodiments, the electrochemical micro-reaction structure has a transparent state in which the light emitted toward the electrochemical micro-reaction structure passes through the electrochemical micro-reaction structure to realize displaying.

In some embodiments, a plurality of the electrochemical micro-reaction structures are provided corresponding to a plurality of the light-emitting units, a plurality of the first transparent electrodes in the respective electrochemical micro-reaction structures are connected with each other and connected with the driving circuit layer, and a plurality of the second transparent electrodes in the respective electrochemical micro-reaction structures are connected with each other and connected with the driving circuit layer; alternatively, the first transparent electrode and the second transparent electrode in the electrochemical micro-reaction structure are connected with the driving circuit layer.

In a second aspect, the disclosure provides a display device including the display panel as described in the first aspect.

Compared with the related art, the above technical solutions provided by embodiments of the disclosure have the following advantages:
by providing the electrochemical micro-reaction structure by the display panel according to the embodiment, light emitted by the light-emitting unit toward the electrochemical micro-reaction structure is reflected by a mirror surface of the electrochemical micro-reaction structure, and light with a large angle is emitted from a gap between front side display pixels of the display panel, thus disturbing light with a large viewing angle of the front side display pixels, so as to realize the peep preventing function during front side displaying. In addition, by providing the electrochemical micro-reaction structure below the substrate, the electrochemical micro-reaction structure can realize the peep preventing function without occupying the pixels of the display panel, thereby increasing the pixel aperture ratio of the display panel.

### BRIEF DESCRIPTION OF THE DRAWINGS

Accompanying drawings herein, which are incorporated in the description and constitute a part of the description, illustrate embodiments according to the disclosure and serve to explain principles of the disclosure together with the description.

In order to more clearly illustrate embodiments of the disclosure or technical solutions in the related art, drawings that need to be used in description of the embodiments or the related art are briefly introduced below, and it will be apparent to those of ordinary skill in the art that other drawings may be obtained based on these drawings without inventive work.

One or more embodiments are illustrated by the corresponding drawings, which do not constitute a limitation of the embodiments. Elements with the same reference numerals in the drawings represent similar elements, and the drawings in the drawings do not constitute a scale limitation unless otherwise specified.

FIG. 1 is a schematic structural view of a display panel according to an embodiment of the present disclosure;

FIG. 2 is a schematic structural view of a display panel in a peep preventing state according to an embodiment of the present disclosure;

FIG. 3 is a schematic structural view of a display panel in single-sided displaying according to an embodiment of the present disclosure;

FIG. 4 is a schematic structural view of a display panel in double-sided displaying according to an embodiment of the present disclosure;

FIG. 5 is a schematic structural view of a display panel in an energized state according to an embodiment of the present disclosure;

FIG. 6 is a schematic structural view of a display panel in another energized state according to an embodiment of the present disclosure;

FIG. 7 is another schematic structural view of a display panel according to an embodiment of the present disclosure; and

FIG. 8 is a schematic structural view of a display device according to an embodiment of the present disclosure.

Description of reference numerals:
P. display panel; U. light-emitting unit; D. display device;
1. substrate;
2. electrochemical micro-reaction structure; 21. first transparent electrode; 22. second transparent electrode; 23, metal cation electrolyte; 24. rough layer; 25. avoidance part;
3. shielding layer; 4. drive circuit layer; 5. pixel definition layer; 6. second transparent anode; 7. second light emitting layer; 8. shielding cathode; 9. first light emitting layer; 10. first transparent anode; 11. encapsulation layer.

### DETAILED DESCRIPTION

In order to make objects, technical solutions, and advantages of embodiments of the disclosure more clear, the technical solutions in the embodiments of the disclosure will be clearly and fully described in combination with the accompanying drawings in the embodiments of the disclosure. Obviously, the embodiments to be described are part of embodiments but not all embodiments of the disclosure. Based on the embodiments in the disclosure, all other embodiments obtained by those of ordinary skill in the art without inventive work shall fall within the scope of the disclosure.

Many different embodiments or examples are disclosed below to realize different structures of the disclosure. In order to simplify the disclosure, components and arrangements of specific examples are described below. Of course, they are only examples and are not intended to limit the disclosure. Furthermore, the present disclosure may repeat reference numerals and/or letters in different examples. The repetition is for simplicity and clarity, and in itself does not indicate the relationship between the various embodiments and/or arrangements discussed.

For the convenience of description, spatial relationship terms can be used herein to describe the relative positional relationship or movement of one element or feature relative to another element or feature as shown in the drawings, such as “inside”, “outside”, “inner”, “outer”, “under”, “below”, “on”, “above”, “front” and “back”. This spatial relationship term is intended to include different orientations of the device in use or operation other than orientations depicted in the drawings. For example, if the device in the drawings has a position turnover, a posture change or a movement state change, these directional indications will change accordingly, for example: Elements described as “under or below other elements or features” will be subsequently oriented as “on or over other elements or features”. Thus, the exemplary term “below” may include both orientations of above and below. The device may be otherwise oriented (rotated by 90 degrees or in other directions), and the spatial relationship description used herein are interpreted accordingly.

In order to solve a problem that the present OLED display panels adopt a structure design of peep preventing sub-pixels to achieve a peep preventing function, which results in a fact that when the display panel does not need the peep preventing function, the structure that realizes the peep preventing function still occupies an aperture ratio, and the display panel has a small pixel aperture ratio in effective displaying, the disclosure provides a display panel, which realizes peep preventing and displaying functions of the display panel through three states of reflection, transmission and shading of an electrochemical micro-reaction structure, which facilitates on and off of the peep preventing function of the display panel. In addition, since the electrochemical micro-reaction structure is provided below a substrate, it does not occupy a sub-pixel structure of the display panel, and can increase a pixel aperture ratio while realizing the peep preventing function.

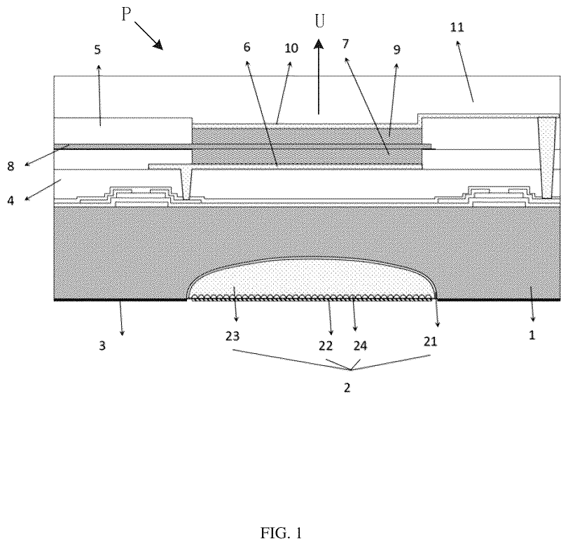

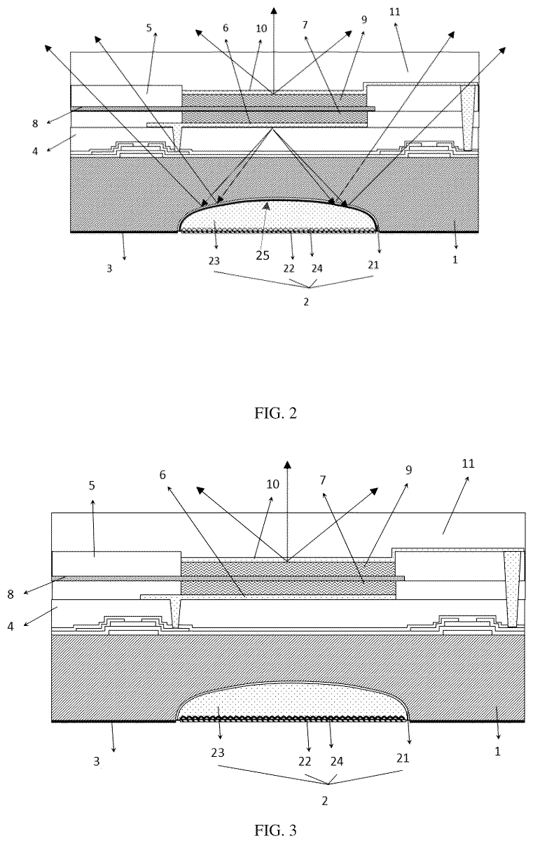

Referring to FIGS. 1 and 2, an embodiment of the disclosure provides a display panel including a substrate 1 and a plurality of light-emitting units provided above the substrate 1, wherein an electrochemical micro-reaction structure 2 is formed on a side of the substrate 1 away from at least one of the light-emitting units, and the light-emitting unit emits light toward the electrochemical micro-reaction structure 2;
the electrochemical micro-reaction structure 2 has a mirror state in which the light emitted toward the electrochemical micro-reaction structure 2 is reflected by the electrochemical micro-reaction structure 2.

With provision of the electrochemical micro-reaction structure 2, light emitted by the light-emitting unit toward the electrochemical micro-reaction structure 2 is reflected by a mirror surface of the electrochemical micro-reaction structure 2, and light with a large angle is emitted from a gap between front side display pixels of the display panel, thus disturbing light with a large viewing angle of the front side display pixels, so as to realize the peep preventing function during front side displaying. In addition, by providing the electrochemical micro-reaction structure 2 below the substrate 1, the electrochemical micro-reaction structure 2 can realize the peep preventing function without occupying the pixels of the display panel, thereby increasing the pixel aperture ratio of the display panel.

The electrochemical micro-reaction structure 2 includes a first transparent electrode 21 and a second transparent electrode 22, between which a cavity is formed, a metal cation electrolyte 23 is provided in the cavity, and a smooth layer is formed on a side of the first transparent electrode 21 toward the second transparent electrode 22.

By applying voltages to the first transparent electrode 21 and the second transparent electrode 22, metal cations in the electrochemical micro-reaction structure 2 are reduced at different places in different voltage states to form a metal layer, and the metal cations can present reflective properties after being reduced, so as to switch among mirror, transparent and shielding black states. Specifically, the metal cations include, but are not limited to, silver ions and zinc ions.

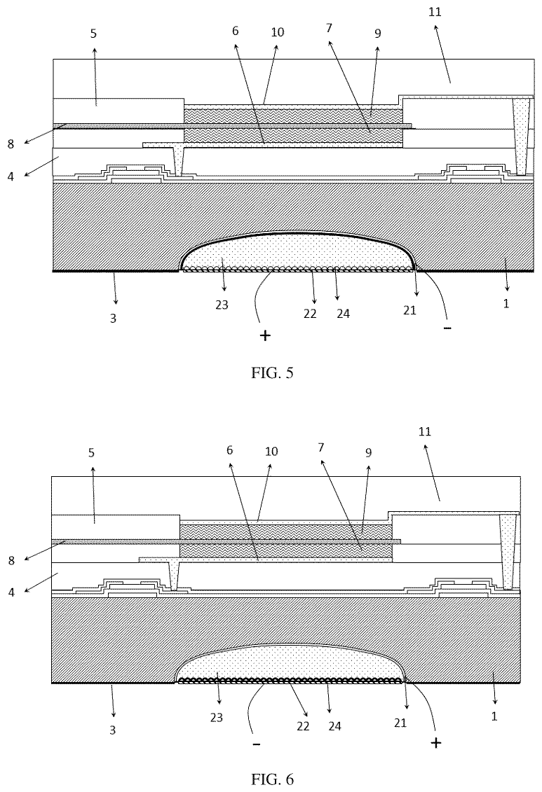

With reference to FIG. 5, when a negative voltage is applied to the first transparent electrode 21 and a positive voltage is applied to the second transparent electrode 22, the metal cation electrolyte 23 in the electrochemical micro-reaction structure 2 gains electrons on a lower surface of the first transparent electrode 21 to form a layer of a metal simple substance, at which time the first transparent electrode 21 and the metal simple substance form a mirror and the electrochemical micro-reaction structure 2 is in a mirror state. The light emitting unit emits light toward the electrochemical micro-reaction structure 2, then the light is reflected by the mirror, and light with a large angle is emitted from a gap between the front side display pixels of the display panel, thus disturbing light with a large viewing angle of the front side display pixels, so as to realize the peep preventing function during front side displaying.

The electrochemical micro-reaction structure 2 is embedded in a side of the substrate 1 away from the light-emitting unit, a shielding layer 3 is further provided on the side of the substrate 1 away from the light-emitting unit, and an avoidance part is formed at a part of the shielding layer 3 corresponding to the electrochemical micro-reaction structure 2. The avoidance part avoids provision of the electrochemical micro-reaction structure 2, and when the electrochemical micro-reaction structure 2 is in a displaying state, the avoidance part does not affect emission of light passing through the electrochemical micro-reaction structure 2, thus ensuring that a backside of the display panel can also serve to display, so that the display panel can realize double-sided displaying. In some embodiments, a projection area of the avoidance part on the substrate 1 is the same as a projection area of the second transparent electrode 22 on the substrate 1. In addition, the shielding layer 3 can provide a support force for the electrochemical micro-reaction structure 2, so as to ensure overall stability of the electrochemical micro-reaction structure 2 and to ensure that the whole backside of the display panel is black during peep preventing.

In some embodiments, the substrate 1 may be a glass substrate, and the electrochemical micro-reaction structure 2 is formed on the substrate 1 by etching a groove or the like to complete preparation. In addition, a glass substrate may be provided on the substrate 1, the electrochemical micro-reaction structure 2 is formed on a side of the glass substrate facing the substrate 1, and the substrate 1 is provided on the glass substrate after the electrochemical micro-reaction structure 2 is provided on the glass substrate.

Referring to FIGS. 5 and 6, the second transparent electrode 22 is located on a side of the first transparent electrode 21 away from the light emitting unit, and a rough layer 24 is formed on a side of the second transparent electrode 22 facing the first transparent electrode 21. When no voltage is applied to the first transparent electrode 21 and the second transparent electrode 22, the light emitted by the light emitting unit toward the electrochemical micro-reaction structure 2 can pass through the electrochemical micro-reaction structure 2, at which time the electrochemical micro-reaction structure 2 is in a displaying state to perform displaying on the backside of the display panel. When no light in the light-emitting unit is emitted toward the electrochemical micro-reaction structure 2, the display panel is in a single-sided displaying state, that is, a front side of the display panel can perform displaying, and the backside of the display panel has no display function. In order to ensure whole black effect of the backside of the display panel at this time, a positive voltage is applied to the first transparent electrode 21 and a negative voltage is applied to the second transparent electrode 22, so that the metal cations in the electrochemical micro-reaction structure 2 are reduced on an upper surface of the second transparent electrode 22, and since the rough layer 24 is formed on the side of the second transparent electrode 22 facing the first transparent electrode 21, the upper surface of the second transparent electrode 22 is a rough surface, and thus a metal simple substance layer formed on the second transparent electrode 22 is in light-absorbing black, at which time the electrochemical micro-reaction structure 2 is in a shielding state, functioning in shielding light.

In some embodiments, particles are sprayed on a surface of the second transparent electrode 22 to form the rough layer 24, and a particle diameter of the particle may be on a micron or nanometer scale. In some embodiments, the rough layer 24 may be formed on the surface of the second transparent electrode 22 by a process such as nanoimprint.

In the disclosure, the light-emitting unit and the electrochemical micro-reaction structure 2 are arranged in a thickness direction of the substrate 1. When the light-emitting unit and the electrochemical micro-reaction structure 2 are arranged side by side, the electrochemical micro-reaction structure 2 occupies an area of the panel and a certain aperture ratio is lost. The electrochemical micro-reaction structure 2 in the display panel according to the disclosure does not occupy the display area, thus reducing loss of the aperture ratio and improving the aperture ratio.

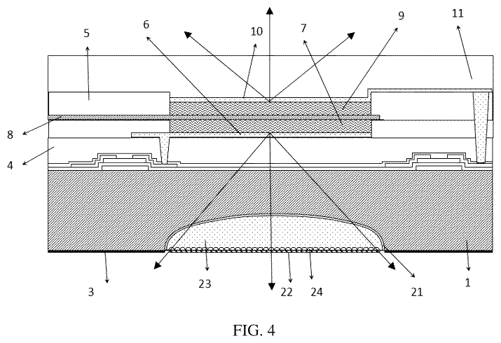

Referring to FIGS. 1 to 4, furthermore, by providing the electrochemical micro-reaction structure 2 between the light-emitting unit and the substrate 1, that is, below the light-emitting unit in the disclosure, the front side of the panel realize displaying and peep preventing functions, and the backside of the panel also realizes a displaying function. Therefore, peep preventing and double-sided displaying can be realized in the disclosure.

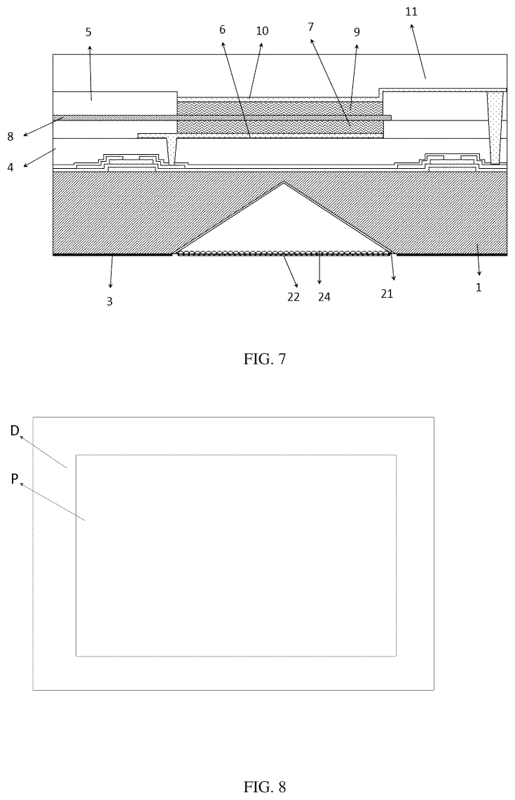

Referring to FIG. 7, an orthogonal projection of the first transparent electrode 21 in a thickness direction of the substrate 1 is in a shape of an arc, a broken line or a polygon. By changing the shape of the orthogonal projection of the first transparent electrode 21 in the thickness direction of the substrate 1, reflection effect of the first transparent electrode 21 is improved. The broken line shape involves a case that orthogonal projections of the first transparent electrode 21 and the second transparent electrode 22 in the thickness direction of the substrate 1 constitute an isosceles triangle, and the broken line for the first transparent electrode 21 has an inflection point, and the orthogonal projections of the first transparent electrode 21 are two sides with the same length of the isosceles triangle. In addition, the broken line may have two, three or more inflection points. Similarly, when the first transparent electrode 21 is a polygon, the orthogonal projections of the first transparent electrode 21 and the second transparent electrode 22 in the thickness direction of the substrate 1 may be rectangle, trapezoid or other polygons.

A driving circuit layer 4 is further provided between the substrate 1 and the light emitting unit and is connected with the first transparent electrode 21 and the second transparent electrode 22, causing a voltage difference between the first transparent electrode 21 and the second transparent electrode 22. Switching between different states of the electrochemical micro-reaction structure 2 is realized by energizing the electrochemical micro-reaction structure 2 by the driving circuit layer 4. Specifically, when no voltage is applied to the first transparent electrode 21 and the second transparent electrode 22, the electrochemical micro-reaction structure 2 is in the displaying state; when the driving circuit layer 4 applies a positive voltage to the first transparent electrode 21 and a negative voltage to the second transparent electrode 22, the metal cations in the electrochemical micro-reaction structure 2 are reduced on the upper surface of the second transparent electrode 22, and the electrochemical micro-reaction structure 2 is switched to the shielding state; when the driving circuit layer 4 applies a positive voltage to the second transparent electrode 22 and a negative voltage to the first transparent electrode 21, metal cations in the electrochemical micro-reaction structure 2 are reduced on an upper surface of the first transparent electrode 21, and the electrochemical micro-reaction structure 2 is switched to the mirror state.

Referring to FIGS. 2 to 4, a plurality of pixel definition layers 5 are provided on a side of the driving circuit layer 4 away from the substrate 1, and a plurality of the light-emitting units are respectively arranged on the respective pixel definition layers 5, and a plurality of the electrochemical micro-reaction structures 2 can also be provided corresponding to a plurality of the light-emitting units. The respective pixel definition layers 5 are independently controlled for displaying by a plurality of the light emitting units.

The light-emitting unit is electrically connected with the driving circuit layer 4 and includes a second light-emitting layer 7 and a first light-emitting layer 9 having opposite light-emitting directions. Specifically, the second light-emitting layer 7 emits light downward to the electrochemical micro-reaction structure 2 which is in the mirror state, and reflects the light with a large angle from the gap between the front side display pixels of the display panel, thus disturbing the light with a large viewing angle of the front side display pixels, so as to realize the peep preventing function during front side displaying. The first light-emitting layer 9 emits light upward, thereby realizing a front side display function of the display panel.

The light-emitting unit further includes a second transparent anode 6, a shielding cathode 8 and a first transparent anode 10 which are sequentially arranged on the driving circuit layer 4 in a direction away from the substrate 1. The first light-emitting layer 9 is provided between the shielding cathode 8 and the first transparent anode 10, and the second light-emitting layer 7 is provided between the second transparent anode 6 and the shielding cathode 8. The first transparent anode 10 and the second transparent anode 6 both indirectly communicate with the shielding cathode 8, and the light-emitting directions of the first light-emitting layer 9 and the second light-emitting layer 7 are opposite. The first light-emitting layer 9 and the second light-emitting layer 7 are separated by the shielding cathode 8, which can prevent interference between the lights emitted by the first light-emitting layer 9 and the second light-emitting layer 7. With the provision of the first transparent anode 10, the first light emitting layer 9 can emit light toward the front side of the panel; with the provision of the second transparent anode 6, the second light-emitting layer 7 can emit light toward the backside of the panel. The first transparent anode 10 and the second transparent anode 6 share the shielding cathode 8, reducing a thickness of the panel while ensuring the display effect.

A first thin film transistor is provided in the driving circuit layer 4 and connected with the first transparent anode 10, so as to control the front side displaying of the display panel; a second thin film transistor is provided in the driving circuit layer 4 and connected with the second transparent anode 6, so as to control backside displaying of the display panel.

A plurality of the first transparent electrodes 21 in the respective electrochemical micro-reaction structures 2 are connected with each other and connected with the driving circuit layer 4, and a plurality of the second transparent electrodes 22 in the respective electrochemical micro-reaction structures 2 are connected with each other and connected with the driving circuit layer 4. Alternatively, the first transparent electrode 21 and the second transparent electrode 22 in the electrochemical micro-reaction structure 2 are connected with the driving circuit layer 4. Specifically, the first transparent electrode 21 and the second transparent electrode 22 in the electrochemical micro-reaction structure 2 are connected with the driving circuit layer 4, that is, each of the electrochemical micro-reaction structures 2 in the display panel is connected with the driving circuit layer 4 independently, so as to realize independent control of each of the electrochemical micro-reaction structures 2 and area control. A plurality of the first transparent electrodes 21 in the respective electrochemical micro-reaction structures 2 are connected with each other and connected with the driving circuit layer 4, and a plurality of the second transparent electrodes 22 in the respective electrochemical micro-reaction structures 2 are connected with each other and connected with the driving circuit layer 4, that is, all of the first transparent electrodes 21 in the display panel are connected with each other and then connected with the driving circuit layer 4, so that the display panel synchronously controls all of the first transparent electrodes 21; and all of the second transparent electrodes 22 in the display panel are connected with each other and then connected with the driving circuit layer 4, so that the display panel synchronously control all of the second transparent electrodes 22.

Referring to FIG. 1, an encapsulation layer 11 is provided on a side of the light-emitting unit away from the substrate 1, and the light-emitting unit is encapsulated, covered and filled by the encapsulation layer 11, thereby effectively isolating the light-emitting unit, achieving encapsulation and isolation effect.

Referring to FIGS. 1 to 6, to sum up, the display panel according to the disclosure has three displaying states. A first state is a peep preventing displaying state, that is, when a negative voltage is applied to the first transparent electrode 21 and a positive voltage is applied to the second transparent electrode 22, the metal cations in the electrochemical micro-reaction structure 2 gain electrons on the lower surface of the first transparent electrode 21 and form a layer of a metal simple substance after a period of time, and at this time, the first transparent electrode 21 and the metal simple substance form a mirror and the electrochemical micro-reaction structure 2 is in the mirror state, the light emitted by the second light-emitting layer 7 can be reflected by the mirror, and the light with a large angle is emitted from a gap between the front side display pixels of the display panel, thus disturbing light with a large viewing angle of the front side display pixels, so as to realize the peep preventing function during front side displaying. When a positive voltage is applied to the first transparent electrode 21 and a negative voltage is applied to the second transparent electrode 22, the metal simple substance on the lower surface of the first transparent electrode 21 loses electrons and gradually dissolves in the electrolyte, so that the whole electrochemical micro-reaction structure 2 is transparent and in the displaying state, and the light emitted by the first light emitting layer 9 and the second light emitting layer 7 can exit normally, thus realizing the second state, namely, the double-sided displaying state. However, with increase of energization time, the metal cations are gradually reduced on the upper surface of the second transparent electrode 22, and the electrochemical micro-reaction structure 2 is in the shielding state. However, since the upper surface of the second transparent electrode 22 is provided with the rough layer 24, the formed metal simple substance layer is in light-absorbing black, which can function in shielding and realize a third state, and at this time, the whole backside of the display panel is black, and the display panel is in the single-sided displaying state. Of course, when no voltage is applied to the first transparent electrode 21 and the second transparent electrode 22, the whole electrochemical micro-reaction structure 2 is also transparent and in the double-sided displaying state.

It should be noted that other components of the display panel are known to those skilled in the art and will not be described in detail herein.

Referring to FIG. 8, an embodiment of the present disclosure further provides a display device which includes the display panel according to the embodiment described above. Technical features of the display panel may refer to the above description, which will not be described in detail here. The display device disclosed in the embodiment of the present disclosure includes the display panel according to the embodiment above, and thus has all of the above technical effect, which will not be described in detail herein. Other components of the display device are known to those skilled in the art and will not be described in detail herein.

The display device may be a single-sided display device, such as a mobile phone, a tablet, a display, a television, and a wearable electronic device. Of course, the display device may also be a double-sided display device, such as a double-sided display mobile phone.

It should be understood that the terms used herein are only for the purpose of describing specific exemplary embodiments and are not intended to be limiting. Unless the context clearly indicates otherwise, the singular forms “a”, “an” and “the” as used herein can also mean including plural forms. The terms “include”, “including”, “comprise” and “comprising” are inclusive and thus indicate the presence of features, steps, operations, elements and/or components described, but do not exclude the presence or addition of one or more other features, steps, operations, elements, components, and/or combinations thereof. The method steps, procedures, and operations described herein are not interpreted as necessarily requiring them to be executed in the specific order described, unless the execution order is explicitly indicated. It should also be understood that additional or alternative steps may be used.

Although a plurality of elements, components, regions, layers and/or sections can be described herein with the terms first, second, third, and the like, they should not be limited by these terms. These terms may be only used to distinguish one element, component, region, layer or section from another ones. Terms such as “first” and “second” and other numerical terms do not imply sequence or order when used herein unless clearly indicated in the context. Accordingly, the first element, component, region, layer or section discussed below may be referred to as a second element, component, region, layer or section without departing from teachings of the exemplary embodiments.

The foregoing description is only the description of embodiments of the disclosure to enable a person skilled in the art to understand or implement the disclosure. Various modifications to these embodiments will be apparent to a person skilled in the art, and general principles defined herein may be implemented in other embodiments without departing from the spirit or scope of the disclosure. Thus, the disclosure is not limited to the embodiments shown herein, but conforms to the widest scope consistent with the principles and novel characteristics applied herein.

What is claimed is:

1. A display panel comprising a substrate and a plurality of light-emitting units provided above the substrate, wherein an electrochemical micro-reaction structure is formed on a side of the substrate away from at least one of the light-emitting units, and the light-emitting unit emits light toward the electrochemical micro-reaction structure;
the electrochemical micro-reaction structure has a mirror state in which the light emitted toward the electrochemical micro-reaction structure is reflected by the electrochemical micro-reaction structure.

2. The display panel according to claim 1, wherein the electrochemical micro-reaction structure comprises a first transparent electrode and a second transparent electrode, between which a cavity is formed, a metal cation electrolyte is provided in the cavity, and a smooth layer is formed on a side of the first transparent electrode toward the second transparent electrode.

3. The display panel according to claim 2, wherein by applying voltages to the first transparent electrode and the second transparent electrode, the metal cations in the electrochemical micro-reaction structure are reduced at different places in different voltage states to form a metal layer.

4. The display panel according to claim 3, wherein when a negative voltage is applied to the first transparent electrode and a positive voltage is applied to the second transparent electrode, the metal cation electrolyte in the electrochemical micro-reaction structure gains electrons on a lower surface of the first transparent electrode to form a layer of a metal simple substance, at which time the first transparent electrode and the metal simple substance form a mirror and the electrochemical micro-reaction structure is in a mirror state.

5. The display panel according to claim 3, wherein when no voltage is applied to the first transparent electrode and the second transparent electrode, the light emitted by the light emitting unit toward the electrochemical micro-reaction structure passes through the electrochemical micro-reaction structure, at which time the electrochemical micro-reaction structure is in a displaying state to perform displaying on a backside of the display panel.

6. The display panel according to claim 3, wherein when a positive voltage is applied to the first transparent electrode and a negative voltage is applied to the second transparent electrode, the metal cations in the electrochemical micro-reaction structure are reduced on an upper surface of the second transparent electrode, and since a rough layer is formed on a side of the second transparent electrode facing the first transparent electrode, the upper surface of the second transparent electrode is a rough surface, and thus a metal simple substance layer formed on the second transparent electrode is in light-absorbing black, at which time the electrochemical micro-reaction structure is in a shielding state.

7. The display panel according to claim 2, wherein the electrochemical micro-reaction structure is embedded in a side of the substrate away from the light-emitting unit which is further provided with a shielding layer, and an avoidance part is formed at a part of the shielding layer corresponding to the electrochemical micro-reaction structure.

8. The display panel according to claim 7, wherein the shielding layer provides a support force for the electrochemical micro-reaction structure.

9. The display panel according to claim 7, wherein the second transparent electrode is located on a side of the first transparent electrode away from the light emitting unit, and a rough layer is formed on a side of the second transparent electrode facing the first transparent electrode.

10. The display panel according to claim 9, wherein an orthogonal projection of the first transparent electrode in a thickness direction of the substrate is in a shape of an arc, a broken line or a polygon.

11. The display panel according to claim 2, wherein a driving circuit layer is further provided between the substrate and the light emitting unit and is connected with the first transparent electrode and the second transparent electrode, causing a voltage difference between the first transparent electrode and the second transparent electrode.

12. The display panel according to claim 11, wherein the light-emitting unit is electrically connected with the driving circuit layer and comprises a second light-emitting layer and a first light-emitting layer having opposite light-emitting directions.

13. The display panel according to claim 12, wherein the electrochemical micro-reaction structure has a transparent state in which the light emitted toward the electrochemical micro-reaction structure passes through the electrochemical micro-reaction structure to realize displaying.

14. The display panel according to claim 12, wherein a plurality of the electrochemical micro-reaction structures are provided corresponding to a plurality of the light-emitting units, a plurality of the first transparent electrodes in the respective electrochemical micro-reaction structures are connected with each other and connected with the driving circuit layer, and a plurality of the second transparent electrodes in the respective electrochemical micro-reaction structures are connected with each other and connected with the driving circuit layer; alternatively, the first transparent electrode and the second transparent electrode in the electrochemical micro-reaction structure are connected with the driving circuit layer.

15. The display panel according to claim 1, wherein the light-emitting unit and the electrochemical micro-reaction structure are arranged in a thickness direction of the substrate.

16. The display panel according to claim 1 comprising a display panel which comprises a substrate and a plurality of light-emitting units provided above the substrate, wherein an electrochemical micro-reaction structure is formed on a side of the substrate away from at least one of the light-emitting units, and the light-emitting unit emits light toward the electrochemical micro-reaction structure;
the electrochemical micro-reaction structure has a mirror state in which the light emitted toward the electrochemical micro-reaction structure is reflected by the electrochemical micro-reaction structure.
